(19) United States
(12) Patent Application Publication
(10) Pub. No.: US 2014/0187138 A1
(43) Pub. Date: Jul. 3, 2014

(54) MOUNTING APPARATUS WITH AIR GUIDING DUCT

(71) Applicants: HON HAI PRECISION INDUSTRY CO., LTD., New Taipei (TW); HONG FU JIN PRECISION INDUSTRY (WuHan) CO., LTD., Wuhan (CN)

(72) Inventor: HAI-YUN WANG, Wuhan (CN)

(73) Assignees: HON HAI PRECISION INDUSTRY CO., LTD., New Taipei (TW); HONG FU JIN PRECISION INDUSTRY (WuHan) CO., LTD., Wuhan (CN)

(21) Appl. No.: 14/011,926

(22) Filed: Aug. 28, 2013

(30) Foreign Application Priority Data
Dec. 27, 2012 (CN) 2012105775040

(51) Int. Cl. H05K 7/20

(52) U.S. Cl. CPC H05K 7/20009
USPC 454/184

(57) ABSTRACT

A mounting apparatus includes a chassis and a mounting bracket. The chassis includes a front plate and a rear plate. A plurality of air intakes is defined in the front plate, and a fan is attached to the rear plate. The mounting bracket includes a front panel, a rear panel, a connecting portion, and an air guiding panel. The air guiding panel is located between the connecting panel and the front plate, and a plurality of ventilation holes is defined in the front panel and the rear panel. The plurality of air intakes, the plurality of ventilation holes, the air guiding panel, and the fan cooperatively define an air passage.

### BACKGROUND

1. Technical Field

The present disclosure relates to mounting apparatuses, and particularly to a mounting apparatus with an air guiding duct.

2. Description of Related Art

Many personal computers include data storage devices, such as hard disk drives (HDDs), floppy disk drives, and compact disc-read only memory (CD-ROM) drives. The data storage devices are received in a bracket, and the bracket is attached to a front plate of a computer enclosure. However, the bracket often prevents air from flowing through the data storage devices, and heat generated by the data storage devices can not be dissipated. Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, cutaway view of a mounting apparatus and two storage devices in accordance with an embodiment.

FIG. 2 is an isometric view of a mounting bracket of the mounting apparatus of FIG. 1.

FIG. 3 is an assembled view of the mounting apparatus of FIG. 1.

FIG. 4 is a schematic view of the mounting apparatus of FIG. 3.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

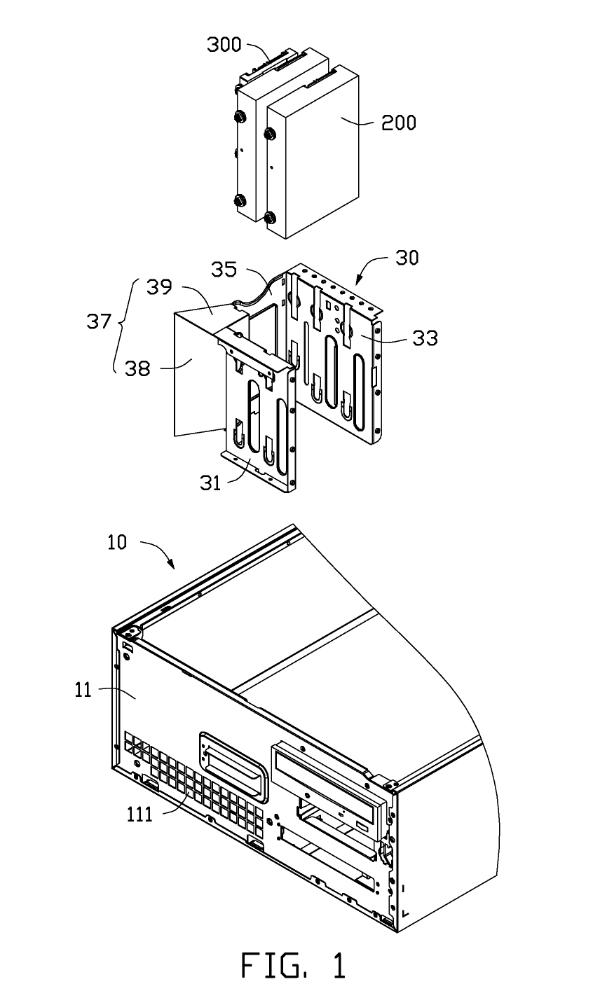

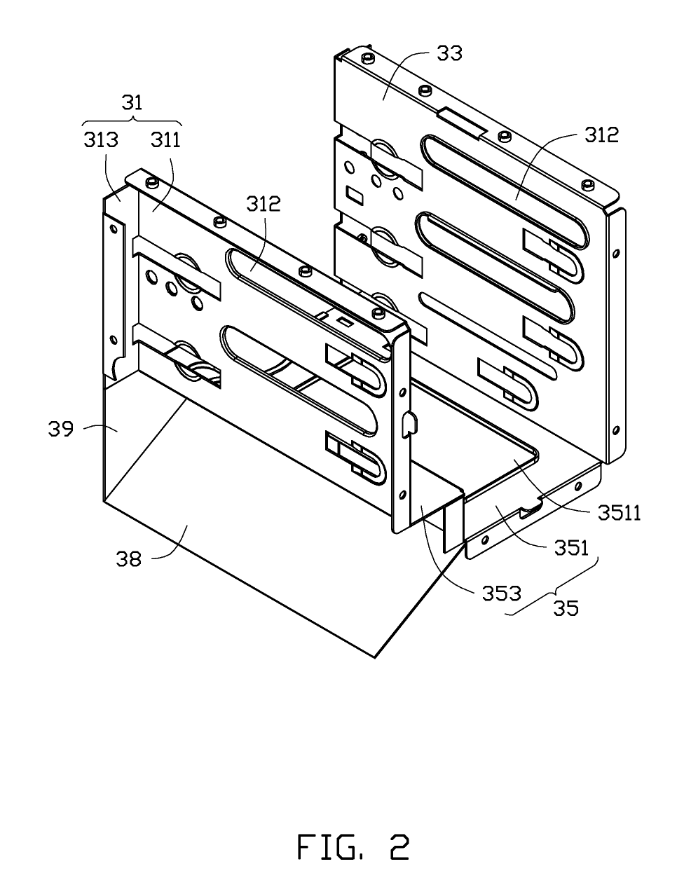

FIGS. 1-2 illustrate a mounting apparatus in accordance with an embodiment. The mounting apparatus comprises a chassis 10 and a mounting bracket 30. The mounting bracket 30 is used to receive a first storage device 200 and a second storage device 300. The first storage device 200 and the second storage device 300 can be hard disk drives (HDDs), floppy disk drives, or compact disc-read only memory (CD-ROM) drives, for example.

The chassis 10 comprises a front plate 11, a rear plate 13, and a bottom plate 15. In one embodiment, the front plate 11 is substantially parallel to the rear plate 13 and perpendicular to the bottom plate 15. A plurality of air intakes 111 is defined in the front plate 11. A fan 131 is secured to the rear plate 13.

The mounting bracket 30 comprises a front panel 31, a rear panel 33, a connecting portion 35, and an air guiding duct 37. In one embodiment, the front panel 31 is substantially parallel to the rear panel 33. The front panel 31 comprises a main body 311 and a flange 313 connected to the main body 311. In one embodiment, the flange 313 is substantially perpendicular to the main body 311. A plurality of ventilation holes 312 is defined in the main body 311 and the rear panel 33.

The connecting portion 35 is connected to the front panel 31 and the rear panel 33. The front panel 31, the rear panel 33, and the connecting portion 35 cooperatively define a space used to receive the first storage device 200 and the second storage device 300. The connecting portion 35 comprises a bottom panel 351 and a connecting panel 353. The bottom panel 351 is connected substantially perpendicular to the rear panel 33. An opening 3511 is defined in the bottom panel 351 for air flowing through. An air guiding hole 3531 is defined in the bottom panel 351. The connecting panel 353 is connected to the bottom panel 351 and the front panel 31. In one embodiment, a cross-section of the connecting panel 353 is L-shaped.

The air guiding duct 37 comprises an air guiding panel 38 and a top panel 39 connected to the air guiding panel 38. The air guiding panel 38 is connected to the bottom panel 351. In one embodiment, the air guiding panel 38 is angled relative to the bottom panel 351, such that an obtuse angle is defined between the air guiding panel 38 and the bottom panel 351. The top panel 39 extends from the flange 313. In one embodiment, the top panel 39 is substantially perpendicular to the air guiding panel 38.

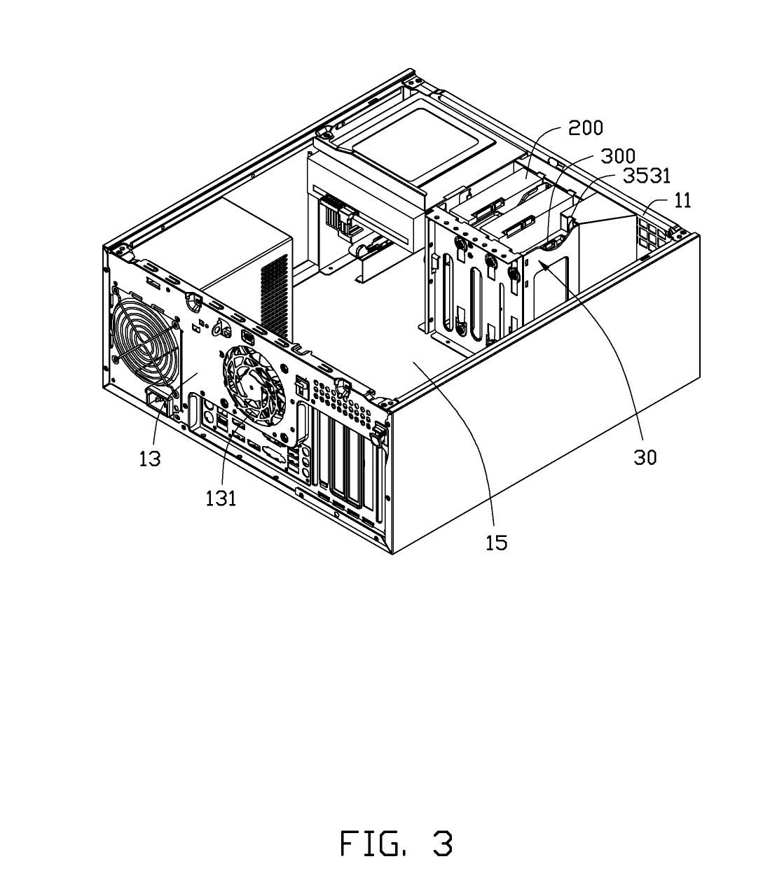

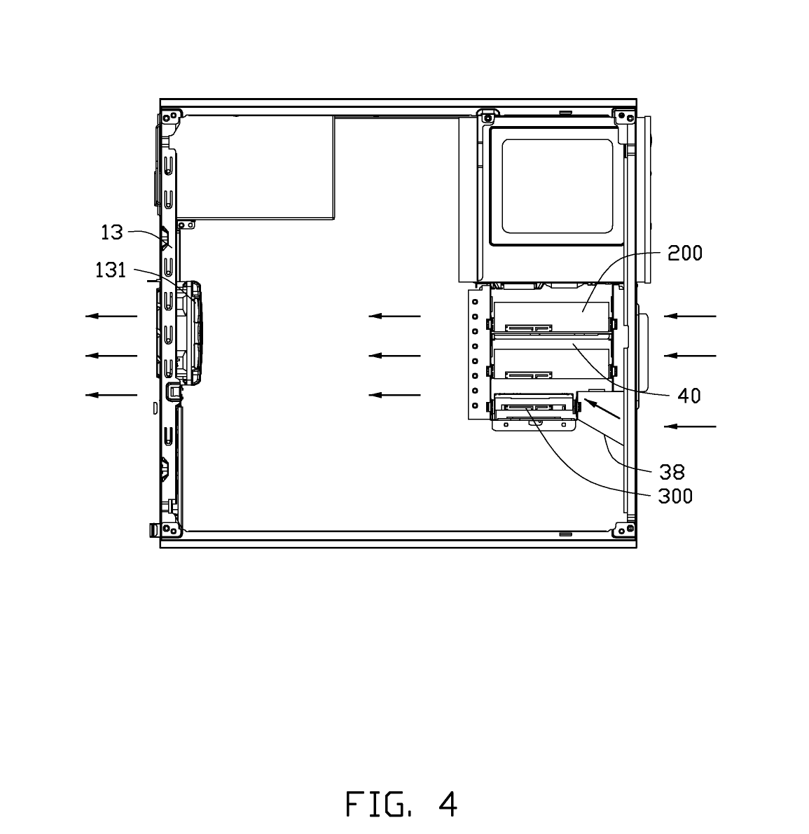

FIG. 3 illustrates that in assembly, the first storage device 200 and the second storage device 300 are located between the front panel 31 and the rear panel 33, and a gap 40 (see FIG. 4) is defined between the first storage device 200 and the second storage device 300. The first storage device 200 and the second storage device 300 are substantially perpendicular to the front panel 31 and the rear panel 33. The mounting bracket 30 is secured in the chassis 10, such that the front panel 31 is substantially parallel to and adjacent to the front plate 11. In one embodiment, a space is defined between the front panel 31 and the front plate 11. A free end of the air guiding panel 38 abuts the front plate 11, and the top panel 39 is connected to the front plate 11 and is substantially parallel to the bottom plate 15.

In use, the fan 131 blows air away from the chassis 10. Air flows into the chassis 10 via the plurality of air intakes 111, and the air guiding duct 37 guides air flowing through first storage device 200 and the second storage device 300. Then, air flows out of the chassis 10 via the fan 131.

In one embodiment, the angle between the air guiding panel 38 and the bottom panel 351 can be adjusted according to the numbers of the first storage device 200 and the second storage device 300. For example, a sharp angle may be defined between the air guiding panel 38 and the bottom panel 351; and the air guiding panel 38 may be substantially parallel to the bottom panel 351. The gap 40 allows air to flow between the first storage device 200 and the second storage device 300, such that heat generated by the first storage device 200 and the second storage device 300 is effectively dissipated.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus comprising:
a chassis comprising a front plate and a rear plate; a plurality of air intakes defined in the front plate, and a fan attached to the rear plate; and
a mounting bracket configured for receiving a storage device; the mounting bracket comprising a front panel, a rear panel, a connecting portion, and an air guiding panel; the air guiding panel are located between the connecting portion and the front plate; and a plurality of ventilation holes defined in the front panel and the rear panel;
wherein the plurality of air intakes, the plurality of ventilation holes, the air guiding panel, and the fan together define an air passage.

2. The mounting apparatus of claim 1, wherein the connecting portion comprises a bottom panel substantially perpendicular to the rear plate, the air guiding panel extends from the bottom panel, and the air guiding panel is angled relative to the bottom panel.

3. The mounting apparatus of claim 2, wherein an obtuse angle is defined between the air guiding panel and the bottom panel.

4. The mounting apparatus of claim 2, wherein the connecting portion further comprises a connecting panel connected to the front panel and the bottom panel, and a cross-section of the connecting panel is substantially L-shaped.

5. The mounting apparatus of claim 1, wherein a free end of the air guiding panel abuts the front plate.

6. The mounting apparatus of claim 1, wherein the mounting bracket further comprises a top panel connected to the air guiding panel, and the top panel abuts the front plate.

7. The mounting apparatus of claim 6, wherein the top panel is substantially perpendicular to the side plate and the air guiding panel.

8. The mounting apparatus of claim 6, wherein the front panel comprises a main body and a flange that is substantially perpendicular to the main body, and the top panel extends from the flange.

9. The mounting apparatus of claim 8, wherein the top panel and the flange are located on a same plane.

10. The mounting apparatus of claim 1, wherein a gap is define between the front panel and the front plate, and the gap is configured to allow air to flow into the mounting bracket via the plurality of ventilation holes of the rear panel.

11. A mounting apparatus comprising:
a chassis comprising a front plate and a rear plate; a plurality of air intakes defined in the front plate; and
a mounting bracket configured for receiving a storage device; the mounting bracket comprising a front panel, a rear panel, a connecting portion, and an air guiding panel; the front panel is substantially parallel to the rear panel and the front plate; the connecting portion comprises a bottom panel substantially perpendicular to the rear panel, and the air guiding panel extends from the bottom panel and angled relative to the bottom panel; a plurality of ventilation holes defined in the front panel and the rear panel;
wherein the air guiding panel abuts the front plate, and the plurality of air intakes, the plurality of ventilation holes, and the air guiding panel together define an air passage for air flowing through.

12. The mounting apparatus of claim 11, wherein an obtuse angle is defined between the air guiding panel and the bottom panel.

13. The mounting apparatus of claim 11, wherein the connecting portion further comprises a connecting panel connected to the front panel and the bottom panel, and a cross-section of the connecting panel is substantially L-shaped.

14. The mounting apparatus of claim 11, wherein the mounting bracket further comprises a top panel connected to the air guiding panel, and the top panel abuts the front plate.

15. The mounting apparatus of claim 14, wherein the top panel is substantially perpendicular to the side plate and the air guiding panel.

16. The mounting apparatus of claim 14, wherein the front panel comprises a main body and a flange that is substantially perpendicular to the main body, and the top panel extends from the flange.

17. The mounting apparatus of claim 16, wherein the top panel and the flange are located on a same plane.

18. The mounting apparatus of claim 11, wherein a gap is define between the front panel and the front plate, and the gap is configured to allow air to flow into the mounting bracket via the plurality of ventilation holes of the rear panel.
